(19) United States
(12) Patent Application Publication
(10) Pub. No.: US 2025/0336877 A1
(43) Pub. Date: Oct. 30, 2025

(54) SEMICONDUCTOR DEVICE

(71) Applicant: Kioxia Corporation, Tokyo (JP)

(72) Inventor: Masayoshi HIGASHIZONO, Yokohama Kanagawa (JP)

(21) Appl. No.: 18/820,120

(22) Filed: Aug. 29, 2024

(30) Foreign Application Priority Data
Apr. 24, 2024 (JP) 2024-070663

(51) Int. Cl. H01L 23/00; H01L 23/31; H01L 23/498; H01L 25/065

(52) U.S. Cl. CPC H01L 24/32; H01L 23/3107; H01L 24/48; H01L 24/73; H01L 25/0655; H01L 23/498; H01L 2224/26175; H01L 2224/32225; H01L 2224/48227; H01L 2224/73215

(57) ABSTRACT

A semiconductor device includes a substrate having a first surface, a first adhesive disposed on the first surface, and a first semiconductor chip disposed on the first adhesive. The semiconductor device further includes a first insulating member disposed on the first surface so as to be in contact with at least a part of the first adhesive. In a first direction perpendicular to the first surface, an upper surface of the first insulating member is higher than or equal to an upper surface of the first adhesive.

### CROSS-REFERENCE TO RELATED APPLICATION(S)

This application is based upon and claims the benefit of priority from Japanese Patent Application No. 2024-070663, filed Apr. 24, 2024, the entire contents of which are incorporated herein by reference.

### FIELD

Embodiments described herein relate generally to a semiconductor device.

### BACKGROUND

A semiconductor package in which a semiconductor chip is disposed on a substrate using an adhesive is known. However, the occurrence of adhesive bleeding, which is spreading and flowing out of the adhesive, has become problematic.

### DESCRIPTION OF THE DRAWINGS

FIG. 1 is a cross-sectional view illustrating a configuration example of a semiconductor device according to a first embodiment.

FIG. 2 is a top view illustrating the configuration example of the semiconductor device according to the first embodiment.

FIG. 3 is an enlarged cross-sectional view illustrating the vicinity of an insulating member of the semiconductor device according to the first embodiment.

FIG. 4 is a flowchart illustrating a method for manufacturing the semiconductor device according to the first embodiment.

FIG. 5 is a schematic cross-sectional view of a step in the method for manufacturing the semiconductor device according to the first embodiment.

FIG. 6 is a schematic cross-sectional view of a step in the method for manufacturing the semiconductor device according to the first embodiment.

FIG. 7 is a schematic cross-sectional view of a step in the method for manufacturing the semiconductor device according to the first embodiment.

FIG. 8 is a schematic cross-sectional view of a step in the method for manufacturing the semiconductor device according to the first embodiment.

FIG. 9 is a schematic cross-sectional view of a step in the method for manufacturing the semiconductor device according to the first embodiment.

FIG. 10 is a schematic cross-sectional view of a step in the method for manufacturing the semiconductor device according to the first embodiment.

FIG. 11 is a cross-sectional view illustrating a configuration example of a semiconductor device according to a first modification of the first embodiment.

FIG. 12 is a cross-sectional view illustrating a configuration example of a semiconductor device according to a second modification of the first embodiment.

FIG. 13 is a top view illustrating the configuration example of the semiconductor device according to the second modification of the first embodiment.

FIG. 14 is an enlarged cross-sectional view illustrating the vicinity of an insulating member of the semiconductor device according to the second modification of the first embodiment.

FIG. 15 is a cross-sectional view illustrating a configuration example of a semiconductor device according to a third modification of the first embodiment.

FIG. 16 is a top view illustrating the configuration example of the semiconductor device according to the third modification of the first embodiment.

FIG. 17 is an enlarged cross-sectional view illustrating the vicinity of an insulating member of the semiconductor device according to the third modification of the first embodiment.

FIG. 18 is a cross-sectional view illustrating the configuration example of the semiconductor device according to the third modification of the first embodiment.

FIG. 19 is a top view illustrating the configuration example of the semiconductor device according to the third modification of the first embodiment.

FIG. 20 is a cross-sectional view illustrating a configuration example of a semiconductor device according to a second embodiment.

FIG. 21 is a top view illustrating the configuration example of the semiconductor device according to the second embodiment.

FIG. 22 is an enlarged cross-sectional view illustrating the vicinity of a side surface of a substrate inside an opening according to the second embodiment.

FIG. 23 is a cross-sectional view illustrating a configuration example of a semiconductor device according to another modification.

FIG. 24 is a cross-sectional view illustrating the configuration example of the semiconductor device according to another modification.

### DETAILED DESCRIPTION

Embodiments provide a semiconductor device capable of preventing adhesive bleeding.

In general, according to one embodiment, there is provided a semiconductor device including a substrate having a first surface, a first adhesive disposed on the first surface, and a first semiconductor chip disposed on the first adhesive. The semiconductor device according to the embodiment further includes a first insulating member disposed on the first surface so as to be in contact with at least a part of the first adhesive. In a first direction perpendicular to the first surface, an upper surface of the first insulating member is higher than or equal to an upper surface of the first adhesive.

Hereinafter, embodiments will be described with reference to the drawings.

The drawings referred to below are schematic, and a relationship between thickness and planar dimension, a thickness ratio of each layer, and the like may differ from actual ones. Further, the drawings may include portions where the dimensional relationships and ratios differ from each other. In the following description, the same reference numeral is given to a component having substantially the same function and configuration. An alphabetic character or the like may be added to the reference numeral to distinguish elements having the same configuration from each other. In this specification, a step includes not only an independent step but also a combination with other steps or other processing.

First, the X-direction, Y-direction, and Z-direction are defined. The X-direction and the Y-direction are directions parallel to a first surface of a substrate, which will be described later. The Z-direction is a direction that intersects (for example, is orthogonal to) the X-direction and the Y-direction. That is, the Z-direction is the thickness direction of an adhesive and insulating member, and is a direction perpendicular to the first surface of the substrate.

### First Embodiment

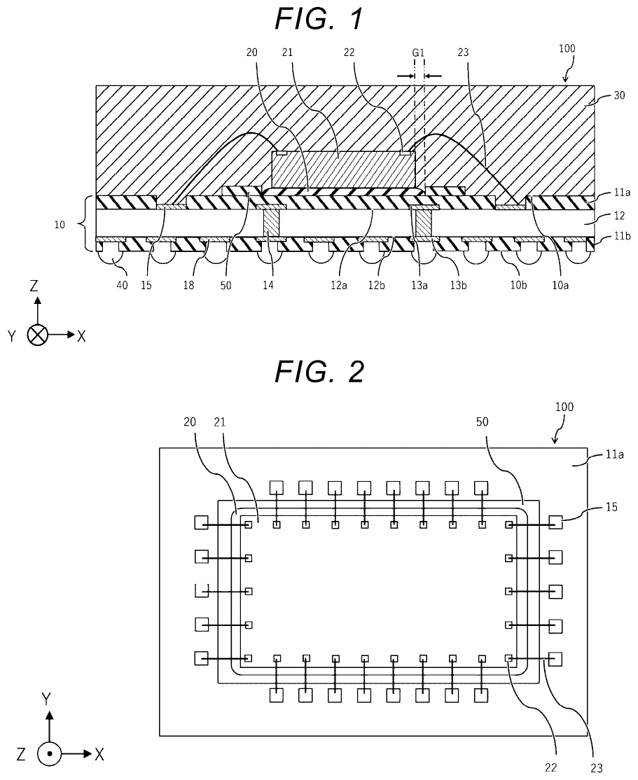

FIG. 1 is a cross-sectional view illustrating a configuration example of a semiconductor device 100 according to the first embodiment. FIG. 2 is a top view illustrating the configuration example of the semiconductor device 100 according to the first embodiment. In FIG. 2, illustration of a sealing resin 30 is omitted. As illustrated in FIG. 1, the semiconductor device 100 includes a substrate 10, an adhesive 20, a semiconductor chip 21, a connecting member 23, the sealing resin 30, a metal bump 40, and a solder resist 50.

The substrate 10 includes solder resists 11a and 11b, a core material 12, wiring layers 13a and 13b, vias 14, pads 15, and electrodes 18. The substrate 10 has a first surface 10a and a second surface 10b opposite to the first surface 10a. The core material 12 has a third surface 12a and a fourth surface 12b opposite to the third surface 12a. For the core material 12, for example, an insulating material such as glass epoxy resin is used. The substrate 10 may have a multilayer wiring structure formed by stacking a plurality of wiring layers and a plurality of insulating layers.

The solder resist 11a is disposed on a third surface 12a of the core material 12. The solder resist 11a covers the third surface 12a of the core material 12 except for a portion corresponding to the pads 15. The solder resist 11a is an example of a first insulating layer. The solder resist 11b is disposed on a fourth surface 12b. The solder resist 11b covers the fourth surface 12b of the core material 12 except for a portion corresponding to the electrodes 18. The solder resist 11b is an example of a second insulating layer. When there is no particular need to distinguish between the solder resists 11a and 11b, the solder resists 11a and 11b will be described as a solder resist 11. The solder resist 11 electrically insulates and protects the wiring layers 13a and 13b.

The wiring layer 13a is disposed on the third surface 12a. The wiring layer 13b is disposed on the fourth surface 12b. The wiring layers 13a and 13b are electrically connected through the vias 14. When there is no particular need to distinguish between the wiring layers 13a and 13b, the wiring layers 13a and 13b will be described as a wiring layer 13.

The pads 15 are disposed on the third surface 12a of the core material 12. Each pad 15 is an example of a first electrode. The pads 15 contain a conductive material such as copper (Cu). The pads 15 may be a part of the wiring layer 13a. The metal bumps 40 are disposed on the second surface 10b of the substrate 10. The metal bumps 40 are electrically connected to the wiring layer 13b through the electrodes 18. The electrodes 18 may be a part of the wiring layer 13b. The metal bumps 40 are made of a conductive material such as solder.

The semiconductor chip 21 is disposed on the first surface 10a with the adhesive 20 interposed therebetween. The semiconductor chip 21 is an example of a first semiconductor chip. The semiconductor chip 21 includes pads 22 on an outer peripheral portion of a front surface thereof. Each pad 22 is an example of a second electrode. The pads 15 and the pads 22 are electrically connected using conductive connecting members 23 such as bonding wires. The pads 15 and the pads 22 are connected in a one-to-one manner. Each connecting member 23 is an example of a first connecting member.

The semiconductor chip 21 may be, for example, a semiconductor chip such as a NAND flash memory, but is not limited thereto. For example, any semiconductor chip may be used, such as a memory element such as a dynamic random access memory (DRAM), an operation element such as a microprocessor, or a signal processing element. The number of semiconductor chips 21 may be one, or a plurality of the semiconductor chips 21 may be stacked.

The adhesive 20 is a thermosetting resin. The adhesive 20 is, for example, an epoxy resin, a polyimide resin, an acrylic resin, or a mixture thereof. As the adhesive 20, for example, a film adhesive such as the die attach film (DAF), the film on wire (FOW) in which a connecting member can be embedded, or the film on device (FOD) in which a semiconductor chip can be embedded is used. In the first embodiment, a case where the adhesive 20 is the DAF will be described. The adhesive 20 is an example of a first adhesive.

When the semiconductor chip 21 is disposed on the first surface 10a, an outer edge of the adhesive 20 may be located outside an outer edge of the semiconductor chip 21. In other words, as illustrated in FIG. 2, a size of an outer shape of the adhesive 20 is larger than a size of an outer shape of the semiconductor chip 21 when viewed in the Z-direction. This spreading and flowing out of the adhesive 20 is hereinafter referred to as bleeding. The ease of bleeding tends to depend on the thickness and elastic modulus of the adhesive.

Returning to the description of FIG. 1, the sealing resin 30 seals the adhesive 20, the semiconductor chip 21, the connecting members 23, the solder resist 50, and the first surface 10a of the substrate 10. For example, thermosetting resin such as epoxy resin is used as the sealing resin 30.

The solder resist 50 is disposed on the first surface 10a of substrate 10 so as to be in contact with at least a part of adhesive 20. The solder resist 50 is an example of a first insulating member. The solder resist 50 is disposed with a gap G1 formed between the solder resist 50 and the semiconductor chip 21 in the X-direction or the Y-direction. In the example illustrated in FIGS. 1 and 2, the solder resist 50 surrounds the entire periphery of the adhesive 20 when viewed in the Z-direction. That is, the solder resist 50 is disposed with a gap G1 formed between the solder resist 50 and all four side surfaces of the semiconductor chip 21. However, the solder resist 50 may not be disposed around the entire periphery of the adhesive 20. Therefore, the solder resist 50 may be disposed in at least a part of the periphery of the adhesive 20 when viewed in the Z-direction.

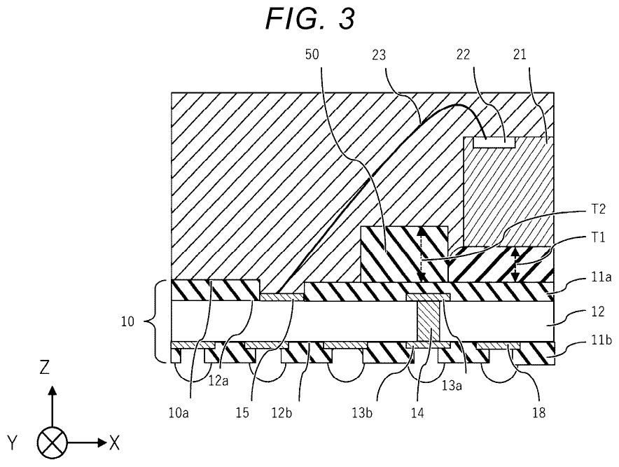

FIG. 3 is an enlarged cross-sectional view illustrating the vicinity of the solder resist 50 of the semiconductor device 100. A thickness T1 of the adhesive 20 in the Z-direction is smaller than (as illustrated in FIG. 3) or equal to a thickness T2 of the solder resist 50 in the Z-direction. That is, the thickness T2 of the solder resist 50 in the Z-direction is greater than (as illustrated in FIG. 3) or equal to the thickness T1 of the adhesive 20 in the Z-direction. In other words, an upper surface of the solder resist 50 is higher than (as illustrated in FIG. 3) or equal to an upper surface of the adhesive 20.

### Method for Manufacturing the Semiconductor Device According to the First Embodiment

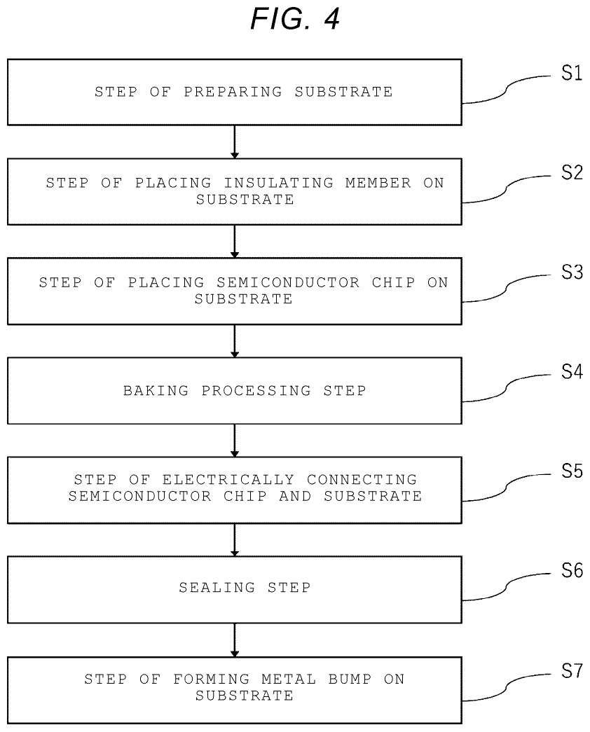

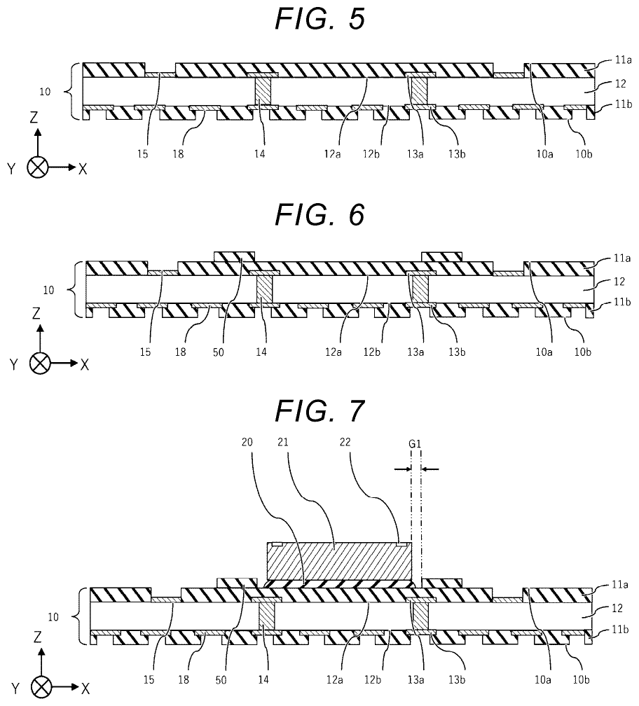

FIG. 4 is a flowchart used to describe a manufacturing process of the semiconductor device 100 according to the first embodiment. Each of FIGS. 5 to 10 is a cross-sectional view illustrating an example of a cross-sectional structure of the semiconductor device 100 according to the first embodiment during manufacture. An example of the manufacturing process of the semiconductor device 100 according to the first embodiment will be described below by appropriately referring to FIG. 4.

### Step S1: Step of Preparing a Substrate

First, through via holes are formed in the core material 12 using a drill or the like. Next, the vias 14 are formed by embedding the inside of the through via holes with copper or the like. The vias 14 may be formed by performing plating on a side surface of the through via holes with copper or the like. Next, the wiring layer 13, the pads 15, and the electrodes 18 are formed by a known pattern forming method. Next, a solder resist is applied to each of the third surface 12a and the fourth surface 12b of the core material 12. Next, a mask is formed on the solder resist applied to each of the third surface 12a and the fourth surface 12b. The mask has openings at positions corresponding to the pads 15 and the electrodes 18. Next, etching is performed using the mask to form the solder resists 11a and 11b. With this, the pads 15 and the electrodes 18 are exposed to the outside. Through the steps described above, the substrate 10 as illustrated in FIG. 5 is manufactured.

### Step S2: Step of Placing an Insulating Member on the Substrate

As illustrated in FIG. 6, the solder resist 50 is disposed on the first surface 10a of the substrate 10 using, for example, a silk printing method. The solder resist 50 may be formed by first forming a mask at a position corresponding to the solder resist 50 after the solder resist is applied to the third surface 12a of the core material 12, and then performing etching using the mask. In this case, the solder resist 50 is a part of the solder resist 11a.

### Step S3: Step of Placing the Semiconductor Chip on the Substrate

As illustrated in FIG. 7, the semiconductor chip 21 with the adhesive 20 attached to a rear surface thereof is disposed on the first surface 10a of the substrate 10. The solder resist 50 is disposed with the gap G1 formed between the solder resist 50 and the semiconductor chip 21 in the X-direction or the Y-direction. In this case, the adhesive 20 may bleed due to stress when the semiconductor chip 21 is disposed on the first surface 10a. Although FIG. 7 illustrates a case where the adhesive 20 and the solder resist 50 are not in contact, the adhesive 20 and the solder resist 50 may come into contact with each other as a result of bleeding.

### Step S4: Baking Processing Step

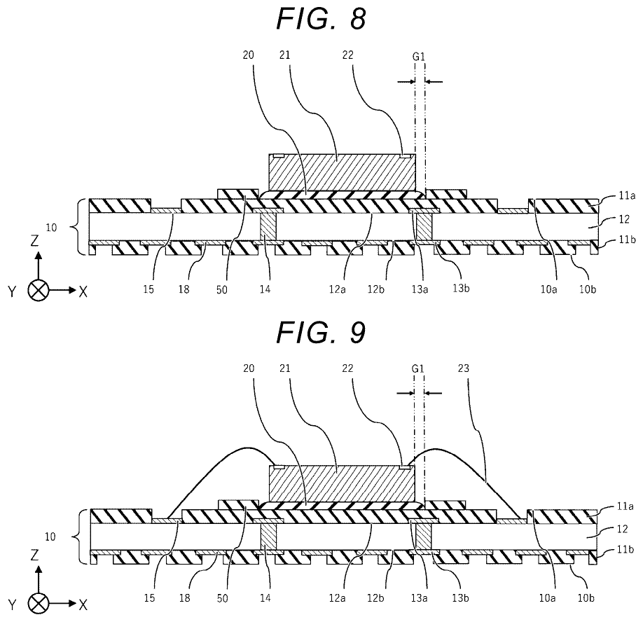

As illustrated in FIG. 8, baking processing is performed to remove moisture and volatile organic substances adhering onto the substrate 10. The adhesive 20 may bleed further as a result of the baking processing. In FIG. 8, the solder resist 50 and at least a part of the adhesive 20 are in contact.

### Step S5: Step of Electrically Connecting the Semiconductor Chip and the Substrate

As illustrated in FIG. 9, the pads 15 formed on the third surface 12a of the core material 12 and the pads 22 formed on the outer peripheral portion of the front surface of the semiconductor chip 21 are electrically connected by the connecting members 23.

### Step S6: Sealing Step

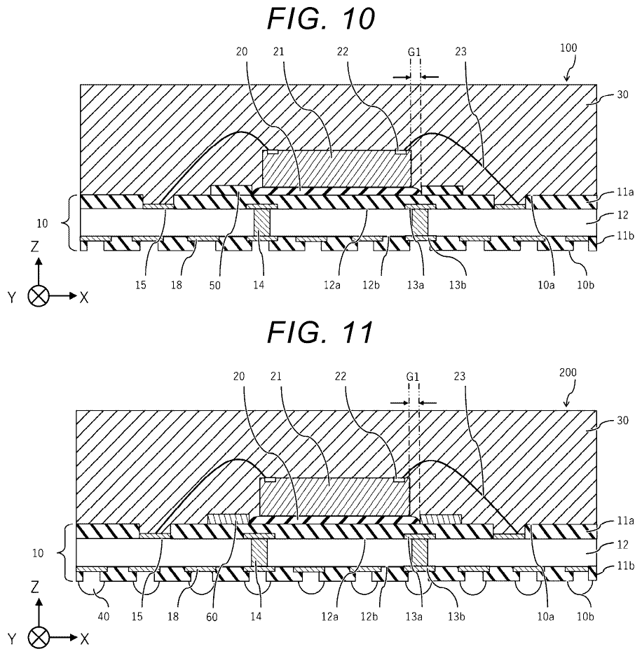

As illustrated in FIG. 10, the entire surface of the first surface 10a of the substrate 10 is covered with the sealing resin 30 so that all of the adhesive 20, the semiconductor chip 21, the connecting members 23, and the solder resist 50 are covered. The sealing resin 30 is cured by a known method such as a drying step, a heat curing step, or an ultraviolet curing step.

### Step S7: Step of Forming the Metal Bump on the Substrate

First, metal balls are mounted on the electrodes 18 to which flux is applied. Next, the metal balls are put in a reflow furnace to melt and bond to the electrodes 18. After that, cleaning is performed to remove the residue of the flux. In this way, the metal bumps 40 are formed on the second surface 10b of the substrate 10. Through the above steps, the semiconductor device 100 according to the first embodiment as illustrated in FIG. 1 is manufactured.

### Effects of the First Embodiment

In the mounting temperature cycling test (TCT), stress is generated due to the difference in thermal expansion coefficient between the semiconductor chip 21 and the substrate 10. In this case, if the adhesive 20 is too thin, there is a concern that the semiconductor chip 21 may peel off from the substrate 10 because the adhesive 20 cannot sufficiently absorb the stress. According to the first embodiment, the solder resist 50 is disposed on the first surface 10a of the substrate 10 so as to be in contact with at least a part of the adhesive 20. Therefore, thinning of the adhesive 20 due to bleeding can be prevented. As a result, the stress between the semiconductor chip 21 and the substrate 10 can be relieved.

Further, according to the first embodiment, since the thickness of the solder resist 50 in the Z-direction is greater than or equal to the thickness of the adhesive 20 in the Z-direction, it is possible to prevent the adhesive 20 from crossing over the solder resist 50 and bleeding. Furthermore, according to the first embodiment, when viewed in the Z-direction, the solder resist 50 surrounds the entire periphery of the adhesive 20, and it is possible to more reliably prevent bleeding of the adhesive 20.

Further, if the flatness of the front surface of the semiconductor chip 21 on which the pads 22 are formed is impaired due to bleeding of the adhesive 20, wire bonding cannot be performed under optimal conditions, and thus, there is a concern that the bonding strength between the pads 22 and the connecting members 23 cannot be ensured. According to the first embodiment, since variations in the thickness T1 of the adhesive 20 in the Z-direction can be prevented by preventing bleeding of the adhesive 20 with the solder resist 50, step S5 (wire bonding) can be performed under optimal conditions. As a result, the bonding strength between the pad 22 and the connecting member 23 can be improved.

### First Modification

FIG. 11 is a cross-sectional view illustrating a configuration example of a semiconductor device 200 according to a first modification of the first embodiment. Hereinafter, the same components as in the first embodiment will be denoted by the same reference numerals, and detailed descriptions thereof will be omitted.

The first modification differs from the first embodiment in the material of the insulating member. That is, the first modification differs from the first embodiment in that the first modification includes epoxy ink 60. The epoxy ink 60 is an example of an insulating member. In the first modification, the epoxy ink 60 is distributed on the first surface 10a using, for example, a silk printing method. In this way, even if the insulating member is made of a different material from the solder resist 11, it is possible to prevent bleeding of the adhesive 20. The basic manufacturing method of the first modification is the same as that of the first embodiment, and according to the first modification, the same or similar effects as in the first embodiment described above can be obtained.

### Second Modification

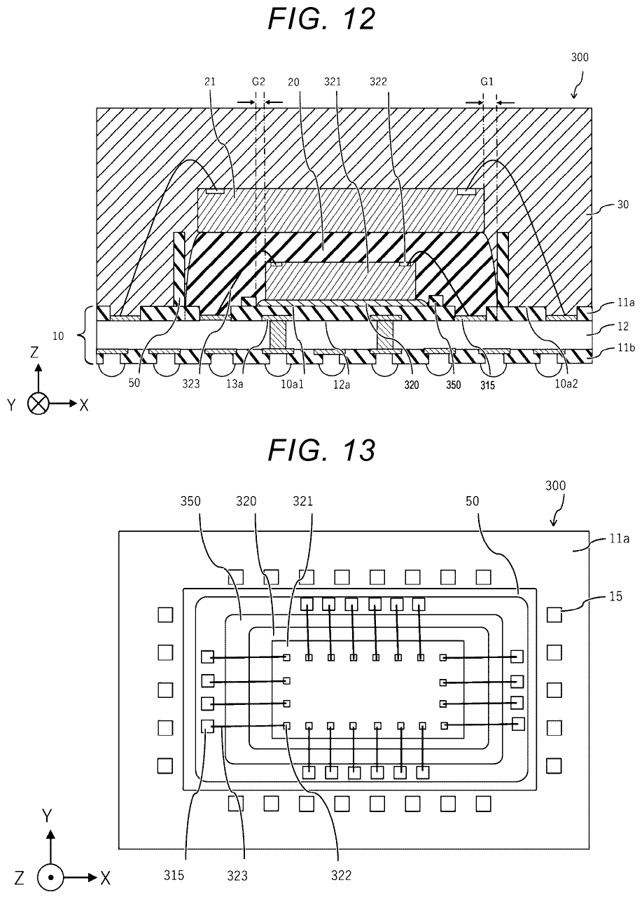

FIG. 12 is a cross-sectional view illustrating a configuration example of a semiconductor device 300 according to a second modification of the first embodiment. FIG. 13 is a top view illustrating the configuration example of the semiconductor device 300 according to the second modification of the first embodiment. In FIG. 13, illustrations of the adhesive 20, the semiconductor chip 21, the connecting members 23, and the sealing resin 30 are omitted. Hereinafter, the same components as in the first embodiment will be denoted by the same reference numerals, and detailed descriptions thereof will be omitted.

The second modification differs from the first embodiment in that the semiconductor device 300 further includes an adhesive 320, a semiconductor chip 321, connecting members 323, and a solder resist 350. In the first embodiment, the case where the adhesive 20 is the DAF is described, but in the second modification, the adhesive 20 is the FOD in which the semiconductor chip 321 is embedded. More specifically, the adhesive 20 covers pads 315, the adhesive 320, the semiconductor chip 321, the connecting members 323, and the solder resist 350.

The first surface 10a includes a first region 10a1 corresponding to the outer shape of the adhesive 20 and a second region 10a2 different from the first region 10a1, when viewed in the Z-direction. The first region 10a1 is an example of a first region, and the second region 10a2 is an example of a second region.

The pads 315 are disposed in a region corresponding to the first region 10a1 of the third surface 12a. Each pad 315 is an example of a third electrode. The pads 315 contain a conductive material such as copper (Cu). The pads 315 may be a part of the wiring layer 13a.

The semiconductor chip 321 is disposed on the first region 10a1 of the first surface 10a with the adhesive 320 interposed therebetween. The semiconductor chip 321 is, for example, a controller. The semiconductor chip 321 has a smaller chip area than the semiconductor chip 21. That is, the semiconductor chip 21 has a larger chip area than the semiconductor chip 321. The semiconductor chip 321 is an example of a second semiconductor chip. The semiconductor chip 321 has pads 322 on an outer peripheral portion of the front surface thereof. Each pad 322 is an example of a fourth electrode. The pads 315 and the pads 322 are electrically connected using the connecting members 323. Each connecting member 323 is an example of a second connecting member. The pads 315 and the pads 322 are connected in a one-to-one manner. The semiconductor chip 321 may be flip-chip mounted on the first region 10a1 of the first surface 10a.

The adhesive 320, which is the DAF, is thinner than the adhesive 20, which is the FOD. That is, the thickness T1 of the adhesive 20 in the Z-direction is larger than a thickness T3 of the adhesive 320 in the Z-direction, which will be described later. The adhesive 320 is an example of a second adhesive. As illustrated in FIG. 13, the size of the outer shape of the adhesive 320 is larger than the size of the outer shape of the semiconductor chip 321 when viewed in the Z-direction.

Returning to the description of FIG. 12, the solder resist 350 is disposed in the first region 10a1 so as to be in contact with at least a part of the adhesive 320. The solder resist 350 is an example of a second insulating member. The solder resist 350 is disposed with a gap G2 formed between the solder resist 350 and the semiconductor chip 321 in the X-direction or the Y-direction. In the example illustrated in FIGS. 12 and 13, the solder resist 350 surrounds the entire periphery of the adhesive 320 when viewed in the Z-direction. That is, the solder resist 350 is disposed with the gap G2 formed between the solder resist 350 and all four side surfaces of the semiconductor chip 321. However, the solder resist 350 may not be disposed around the entire periphery of the adhesive 320. Therefore, the solder resist 350 may be disposed in at least a part of the periphery of the adhesive 320 when viewed in the Z-direction.

FIG. 14 is an enlarged cross-sectional view illustrating the vicinity of the solder resist 350 of the semiconductor device 300. The thickness T3 of the adhesive 320 in the Z-direction is smaller than (as illustrated in FIG. 14) or equal to a thickness T4 of the solder resist 350 in the Z-direction. That is, the thickness T4 of the solder resist 350 in the Z-direction is greater than (as illustrated in FIG. 14) or equal to the thickness T3 of the adhesive 320 in the Z-direction. In other words, an upper surface of the solder resist 350 is higher than (as illustrated in FIG. 14) or equal to an upper surface of the adhesive 320.

The basic manufacturing method of the second modification is the same as that of the first embodiment, and according to the second modification, the same or similar effects as in the first embodiment described above can be obtained. Further, in the second modification, since the semiconductor chip 321 is embedded in the adhesive 20, it is possible to reduce the size of the semiconductor device 300 in the Z-direction.

According to the second modification, the adhesive 20 having a thickness capable of embedding the semiconductor chip 321 may be swollen in the Z-direction due to the occurrence of bleeding. Such swelling of the adhesive 20 may cause voids when another semiconductor chip is stacked on the semiconductor chip 21. According to the second modification, the solder resist 50 is disposed on the first surface 10a of the substrate 10 so as to be in contact with at least a part of the adhesive 20. Therefore, even if the bleeding of the adhesive 20 occurs, the adhesive 20 can be prevented from swelling in the Z-direction.

### Third Modification

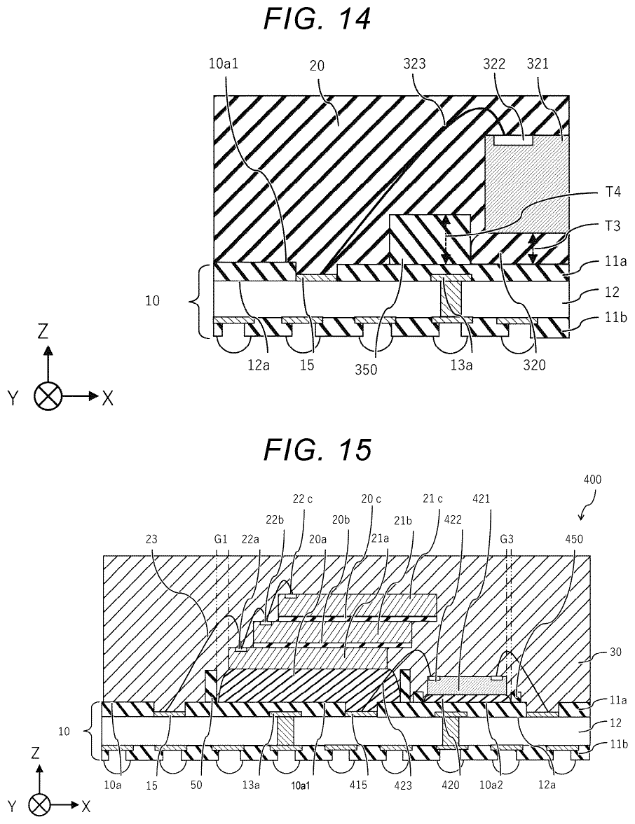

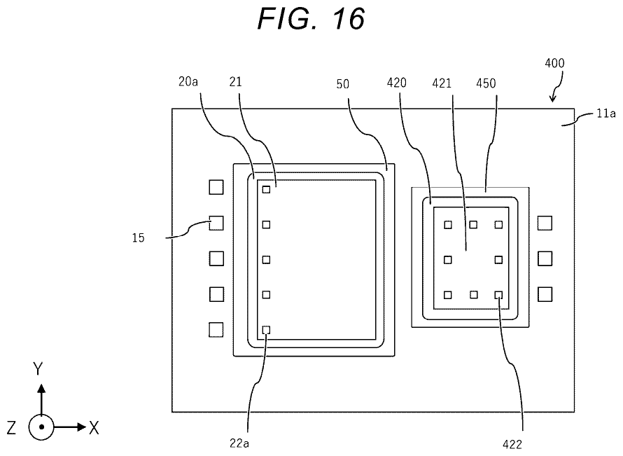

FIG. 15 is a cross-sectional view illustrating a configuration example of a semiconductor device 400 according to a third modification of the first embodiment. FIG. 16 is a top view illustrating the configuration example of the semiconductor device 400 according to the third modification of the first embodiment. In FIG. 16, illustrations of adhesives 20b and 20c, semiconductor chips 21b and 21c, the connecting members 23 and 423, and the sealing resin 30 are omitted. Hereinafter, the same components as in the first embodiment will be denoted by the same reference numerals, and detailed descriptions thereof will be omitted.

In the first embodiment, the case in which one semiconductor chip 21 is disposed on the first surface 10a is described, but in the third modification, as illustrated in FIG. 15, a plurality of semiconductor chips 21a to 21c are stacked in a stepped manner and disposed on the first surface 10a. The plurality of semiconductor chips 21a to 21c respectively include the pads 22a to 22c on the respective surfaces thereof. The pads 15 and the pads 22a to 22c are electrically connected using the connecting members 23.

The semiconductor chip 21a is disposed in the first region 10a1 of the first surface 10a with an adhesive 20a interposed therebetween. The semiconductor chip 21b is disposed on the semiconductor chip 21a with the adhesive 20b interposed therebetween so as not to cover the pads 22a, with the semiconductor chip 21b being shifted in the X-direction with respect to the semiconductor chip 21a. The semiconductor chip 21c is disposed on the semiconductor chip 21b with the adhesive 20c interposed therebetween so as not to cover the pads 22b, with the semiconductor chip 21c being shifted in the X-direction with respect to the semiconductor chip 21b.

In the first embodiment, the case where the adhesive 20 is DAF is described, but in the third modification, the adhesive 20a is the FOW in which at least a part of the connecting member 423 is embedded. More specifically, the adhesive 20a covers the pad 415 and at least a part of one connecting member 423. The adhesives 20b and 20c are the DAF.

The third modification further differs from the first embodiment in that the semiconductor device 400 further includes an adhesive 420, a semiconductor chip 421, the connecting member 423, and a solder resist 450.

The pad 415 is disposed in a region corresponding to the first region 10a1 of the third surface 12a. The pad 415 is an example of a third electrode. The pad 415 contains a conductive material such as copper (Cu). The pad 415 may be a part of the wiring layer 13a.

The semiconductor chip 421 is disposed in the second region 10a2 of the first surface 10a, which is different from the first region 10a1, with the adhesive 420 interposed therebetween. The semiconductor chip 421 is, for example, a controller. The semiconductor chip 421 is an example of a second semiconductor chip. The semiconductor chip 421 has pads 422 on an outer peripheral portion of the front surface thereof. Each pad 422 is an example of a fourth electrode. The pads 15, 415 and the pads 422 are electrically connected using the connecting members 423. Each connecting member 423 is an example of a second connecting member. The pads 15, 415 and the pads 422 are connected in a one-to-one manner.

The adhesive 420, which is the DAF, is thinner than the adhesive 20a, which is the FOW. That is, the thickness T1 of the adhesive 20a in the Z-direction is larger than a thickness T5 of the adhesive 420 in the Z-direction, which will be described later. The adhesive 420 is an example of a second adhesive. As illustrated in FIG. 16, the size of the outer shape of the adhesive 420 is larger than the size of the outer shape of the semiconductor chip 421 when viewed in the Z-direction.

FIG. 17 is an enlarged cross-sectional view illustrating the vicinity of the solder resist 450 of the semiconductor device 400. The thickness T5 of the adhesive 420 in the Z-direction is smaller than (as illustrated in FIG. 17) or equal to a thickness T6 of the solder resist 450 in the Z-direction. That is, the thickness T6 of the solder resist 450 in the Z-direction is greater than (as illustrated in FIG. 17) or equal to the thickness T5 of the adhesive 420 in the Z-direction. In other words, an upper surface of the solder resist 450 is higher than (as illustrated in FIG. 17) or equal to an upper surface of the adhesive 420.

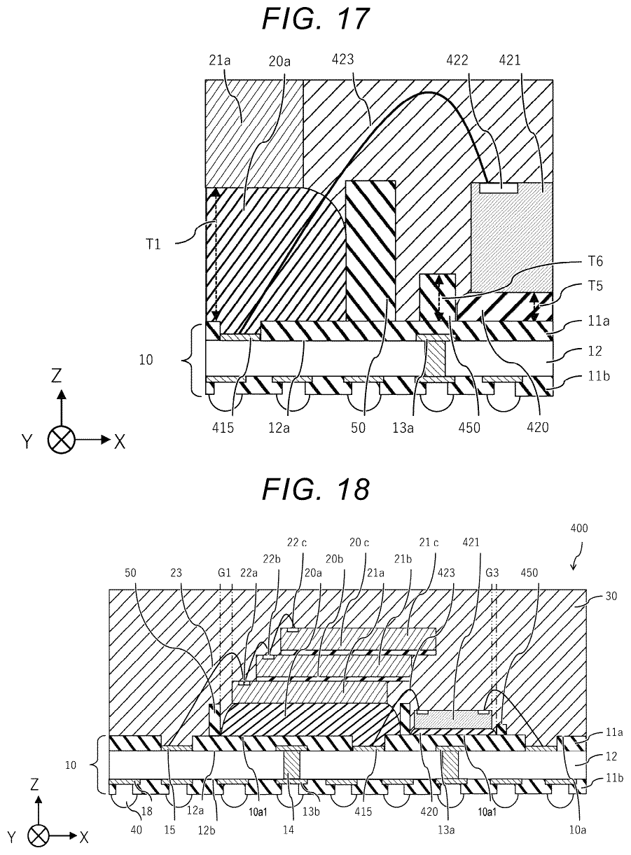

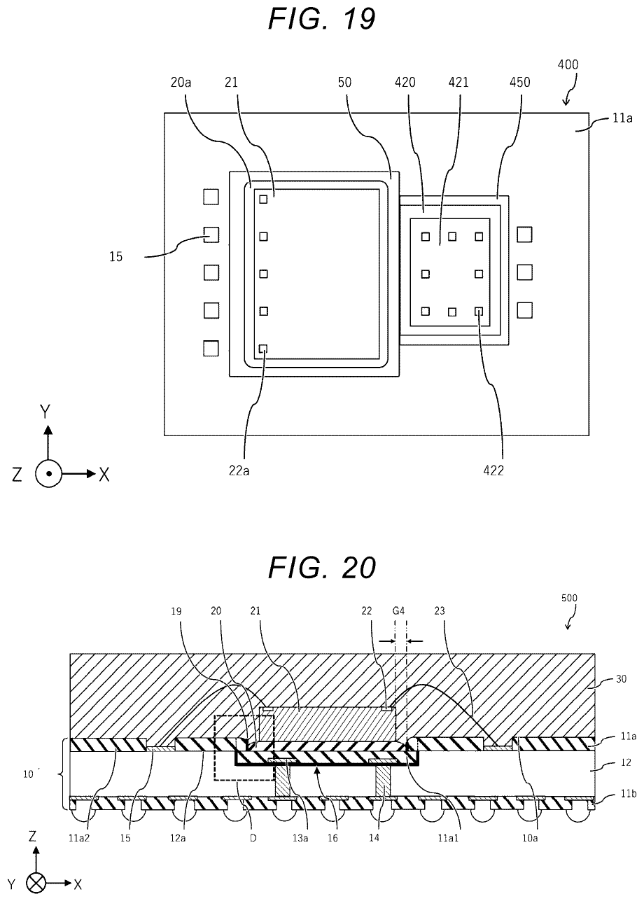

Returning to the description of FIG. 15, the solder resist 450 is disposed in the second region 10a2 of the first surface 10a so as to be in contact with at least a part of the adhesive 420. The solder resist 450 is an example of a second insulating member. The solder resist 450 is disposed with a gap G3 formed between the solder resist 450 and the semiconductor chip 421 in the X-direction or the Y-direction. In the example illustrated in FIGS. 15 and 16, the solder resist 450 surrounds the entire periphery of the adhesive 420 when viewed in the Z-direction. That is, the solder resist 450 is disposed with the gap G3 formed between the solder resist 450 and all four side surfaces of the semiconductor chip 421. However, as illustrated in FIGS. 18 and 19, the solder resist 450 may not be disposed around the entire periphery of the adhesive 420. Therefore, the solder resist 450 may be disposed in at least a part of the periphery of the adhesive 420 when viewed in the Z-direction. As illustrated in FIG. 19, the solder resist 450 is disposed in contact with one side of the frame-shaped solder resist 50. In this way, the entire periphery of the adhesive 420 may be surrounded by the solder resists 50 and 450.

The basic manufacturing method of the third modification is the same as that of the first embodiment, and according to the third modification, the same or similar effect as in the first embodiment described above can be obtained.

According to the third modification, the semiconductor chip 421 is disposed in the second region 10a2 different from the first region 10a1 of the first surface 10a where the adhesive 20a is disposed. In such a case, since at least a part of one connecting member 423 is embedded in the adhesive 20a, it is possible to reduce the size of the semiconductor device 400 in the X-direction or the Y-direction.

### Second Embodiment

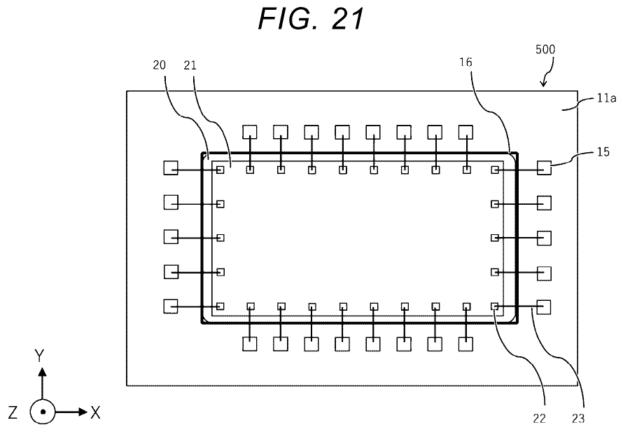

FIG. 20 is a cross-sectional view illustrating a configuration example of a semiconductor device 500 according to the second embodiment. FIG. 21 is a top view illustrating the configuration example of the semiconductor device 500 according to the second embodiment. In FIG. 21, illustration of the sealing resin 30 is omitted. Hereinafter, the same components as in the first embodiment will be denoted by the same reference numerals, and detailed descriptions thereof will be omitted.

The second embodiment differs from the first embodiment in that a substrate 10′ has an opening 16 and that no insulating member (e.g., solder resist 50) is disposed on the first surface 10a of the substrate 10′.

The solder resist 11a has a first portion 11a1 disposed in the opening 16 and a second portion 11a2 disposed outside the opening 16. The shape of the solder resist 11a corresponds to the shape of the opening 16.

The semiconductor chip 21 is disposed in the opening 16 of the substrate 10′ with the adhesive 20 interposed therebetween. The semiconductor chip 21 is disposed in the opening 16 with a gap G4 formed between the semiconductor chip 21 and a side surface 19 of the substrate 10′ in the opening 16. At least a part of the adhesive 20 is in contact with the side surface 19 of the substrate 10′ in the opening 16. As illustrated in FIG. 21, the size of the outer shape of the opening 16 is larger than the size of the outer shape of the semiconductor chip 21 when viewed in the Z-direction.

FIG. 22 is an enlarged cross-sectional view illustrating the vicinity of the side surface 19 of the substrate 10′ in the opening 16. FIG. 22 is also an enlarged view of the dotted line frame D in FIG. 20. A thickness T7 of the second portion 11a2 of the solder resist 11a in the Z-direction is greater than (as illustrated in FIG. 22) or equal to the thickness T1 of the adhesive 20 in the Z-direction. That is, the depth of the opening 16 in the Z-direction is greater than (as illustrated in FIG. 22) or equal to the thickness T1 of the adhesive 20 in the Z-direction.

The basic manufacturing method of the second embodiment is the same as that of the first embodiment, and according to the second embodiment, the same or similar effects as in the first embodiment described above can be obtained. In particular, since the second embodiment has a configuration in which no insulating member is provided, it becomes possible to reduce the cost related to the material of the insulating member.

### Other Modifications

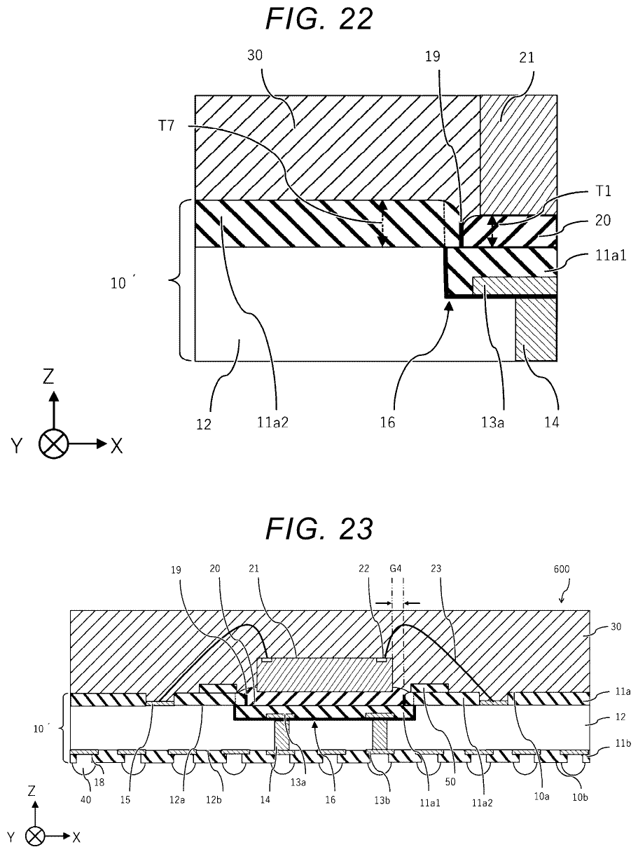

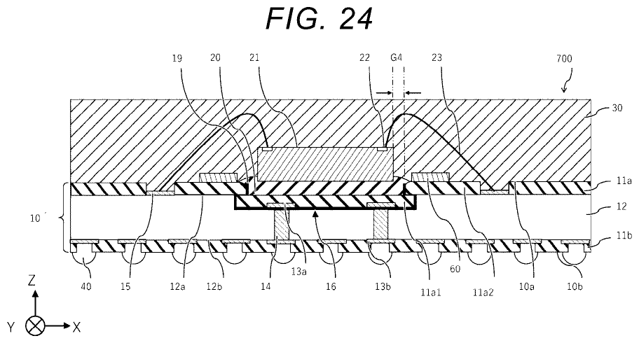

The embodiments and modifications described above may be combined with each other to the extent possible. For example, as illustrated in FIG. 23, the first embodiment can be combined with the second embodiment. Further, as illustrated in FIG. 24, the first modification of the first embodiment can be combined with the second embodiment.

While certain embodiments have been described, these embodiments have been presented by way of example only, and are not intended to limit the scope of the disclosure. Indeed, the novel embodiments described herein may be embodied in a variety of other forms; furthermore, various omissions, substitutions, and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a substrate having a first surface;
a first adhesive disposed on the first surface;
a first semiconductor chip disposed on the first adhesive;
a first insulating member disposed on the first surface so as to be in contact with at least a part of the first adhesive, wherein
in a first direction perpendicular to the first surface, an upper surface of the first insulating member is higher than or equal to an upper surface of the first adhesive.

2. The semiconductor device according to claim 1, further comprising;
a sealing resin disposed on the first surface and covering the first semiconductor chip, wherein
the first insulating member is disposed with a gap formed between the first insulating member and the first semiconductor chip in a second direction parallel to the first surface and the gap is filled with the sealing resin.

3. The semiconductor device according to claim 1, wherein
when viewed in the first direction, the first insulating member surrounds the entire periphery of the first adhesive.

4. The semiconductor device according to claim 1, wherein
when viewed in the first direction, a size of an outer shape of the first adhesive is larger than a size of an outer shape of the first semiconductor chip.

5. The semiconductor device according to claim 1, wherein
the substrate includes a first electrode on the first surface,
the first semiconductor chip includes a second electrode on an outer peripheral portion of a front surface thereof, and
the semiconductor device further comprises a first connecting member that electrically connects the first electrode and the second electrode.

6. The semiconductor device according to claim 5, wherein
the substrate includes a third electrode in a first region where the first adhesive is disposed,
the semiconductor device further comprises
a second adhesive disposed in a second region different from the first region,
a second semiconductor chip disposed on the second adhesive in the second region and including a fourth electrode on an outer peripheral portion of a front surface thereof,
a second insulating member disposed in the second region so as to be in contact with at least a part of the second adhesive, and
a second connecting member that electrically connects the third electrode and the fourth electrode, and at least a part of the second connecting member is embedded in the first adhesive.

7. The semiconductor device according to claim 1, further comprising:
a second adhesive disposed on the first surface;
a second semiconductor chip disposed on the second adhesive; and
a second insulating member disposed on the first surface so as to be in contact with at least a part of the second adhesive, wherein
a thickness of the first adhesive in the first direction is greater than a thickness of the second adhesive in the first direction, and
the first adhesive embeds the second semiconductor chip, the second adhesive, and the second insulating member.

8. The semiconductor device according to claim 7, wherein
a thickness of the second insulating member in the first direction is greater than or equal to a thickness of the second adhesive in the first direction.

9. The semiconductor device according to claim 1, wherein
the substrate has a second surface opposite to the first surface, and further includes a first insulating layer on the first surface and a second insulating layer on the second surface.

10. The semiconductor device according to claim 9, wherein
the first insulating member is made of the same material as the first and second insulating layers.

11. The semiconductor device according to claim 9, wherein
the first insulating member is made of a material that is different from a material of the first and second insulating layers.

12. A semiconductor device comprising:
a substrate having a first surface and a second surface opposite to the first surface and including an opening on the first surface;
a first adhesive disposed in the opening such that at least a part thereof contacts a side surface of the substrate in the opening; and
a first semiconductor chip disposed on the first adhesive, wherein
a depth of the opening in a first direction perpendicular to the first surface is equal to or greater than a thickness of the first adhesive in the first direction.

13. The semiconductor device according to claim 12, wherein
the substrate further includes a first insulating layer on the first surface and a second insulating layer on the second surface, and
the first insulating layer further includes a first portion disposed in the opening and a second portion disposed outside the opening.

14. The semiconductor device according to claim 12, wherein
when viewed in the first direction, a size of an outer shape of the opening is larger than a size of an outer shape of the first semiconductor chip.

15. The semiconductor device according to claim 12, wherein
the substrate includes a first electrode on the first surface,
the first semiconductor chip includes a second electrode on an outer peripheral portion of a front surface thereof, and
the semiconductor device further comprises
a first connecting member that electrically connects the first electrode and the second electrode, and
a sealing resin disposed on the first surface and covering the first semiconductor chip, the first adhesive, and the first connecting member.

16. A semiconductor device comprising:
a substrate having a first surface and a second surface opposite to the first surface;
a first adhesive disposed on the first surface;
a first semiconductor chip disposed on the first adhesive;
a first insulating member surrounding a periphery of the first adhesive and disposed on the first surface so as to be in contact with at least a part of the first adhesive when viewed in a first direction perpendicular to the first surface;
a second adhesive that embeds the first semiconductor chip, the first adhesive, and the first insulating member;
a second semiconductor chip having a larger chip area than the first semiconductor chip and disposed on the first surface via the second adhesive; and
a second insulating member surrounding a periphery of the second adhesive and disposed on the first surface so as to be in contact with at least a part of the second adhesive when viewed in the first direction.

17. The semiconductor device according to claim 16, wherein
the first insulating member is disposed with a gap formed between the first insulating member and the first semiconductor chip in a second direction parallel to the first surface, and
the second insulating member is disposed with a gap formed between the second insulating member and the second semiconductor chip in the second direction.

18. The semiconductor device according to claim 16, wherein
the substrate further includes a first insulating layer on the first surface and a second insulating layer on the second surface, and
the first and second insulating members are made of the same material as the first and second insulating layers.

19. The semiconductor device according to claim 16, wherein
the substrate further includes a first insulating layer on the first surface and a second insulating layer on the second surface, and
the first and second insulating members are made of a material different from a material of the first and second insulating layers.

20. The semiconductor device according to claim 16, wherein
when viewed in the first direction, a size of an outer shape of the first adhesive is larger than a size of an outer shape of the first semiconductor chip, and
when viewed in the first direction, a size of an outer shape of the second adhesive is larger than a size of an outer shape of the second semiconductor chip.
